(19) United States
(12) Patent Application Publication
(10) Pub. No.: US 2020/0203556 A1
(43) Pub. Date: Jun. 25, 2020

(54) METHOD OF MANUFACTURING OPTOELECTRONIC STRUCTURES PROVIDED WITH COPLANAR LIGHT EMITTING DIODES

(71) Applicants: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris Cedex (FR)

(72) Inventors: Guy FEUILLET, Grenoble Cedex (FR); Benjamin DAMILANO, Nice (FR); Jean-Yves DUBOZ, Valbonne (FR); Christophe LARGERON, Grenoble Cedex (FR)

(73) Assignees: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris Cedex (FR)

(21) Appl. No.: 16/715,018

(22) Filed: Dec. 16, 2019

(30) Foreign Application Priority Data
Dec. 20, 2018 (FR) 18 73508

(51) Int. Cl. H01L 33/00; H01L 33/44; H01L 33/36; H01L 27/15

(52) U.S. Cl. CPC H01L 33/007; H01L 33/44; H01L 33/36; H01L 33/06; H01L 27/15; H01L 2933/0025; H01L 2933/0016; H01L 33/0079

(57) ABSTRACT

The invention relates to a method of manufacturing at least one optoelectronic structure on a support substrate.

In particular, this invention relates to manufacturing of an optoelectronic structure that has a plurality of coplanar light emitting diodes, and formed from a succession of light emitting stacks.

Therefore this invention uses a cavity, the bottom of which has a staged profile, such that the formation of the succession of light emitting stacks reproduces the staged profile of the bottom of the cavity, on its exposed face.

Performance of a step to level the succession of light emitting stacks relative to a reference level defined by the exposed surface portion vertically in line with the deepest step, then makes it possible to reveal a set of coplanar light emitting diodes.

### TECHNICAL FIELD

This invention relates to the field of light emitting diodes.

In particular, this invention relates to the field of light emitting diodes used for the display and/or projection of images, but also for lighting.

In this respect, this invention relates to a method for fabrication of an optoelectronic structure provided with light emitting diodes arranged to be coplanar.

### STATE OF PRIOR ART

Beyond their use in public or private lighting, light emitting devices are used nowadays in very many applications, particularly for lithography, communication in visible light (“LIFI” or “Light Fidelity”), anti-dazzle lights for automobile vehicles, head-up displays or “near-eye” displays.

These devices are generally equipped with a pixel matrix, each of which is intended to emit electromagnetic radiation for the formation of images or for lighting.

Depending on the target application, the size of the pixels can vary between one and several tens of micrometres, or even as large as a fraction of a millimetre.

For example, if the display is intended for “near-eye” applications, the size of the pixels is of the order of one micrometre, whereas several tens of micrometres may be required for lighting.

In any case, all these applications require the use of pixels that might emit intense radiation, and that can create a strong contrast when an image is to be displayed.

In this respect, Organic Light Emitting Diodes (OLED), the operation of which enable direct light emission, are now used for “near-eye” applications.

However, the intensity of light radiation emitted by an OLED is still limited to a few 10³ Cd/m², such that these OLEDs cannot presently be envisaged for other applications.

Furthermore, OLEDs are very sensitive to their environment and particularly to humidity and temperature variations.

For automobile lighting, the use of inorganic micro light emitting diodes capable of emitting blue electromagnetic radiation could be considered, and this radiation could be converted into white light, for example using quantum boxes or nanocrystal converters.

This principle can also be used to convert from blue to green and to red, with pixels containing different converters, so as to obtain the three primary colours on a matrix.

However, such a solution requires a complicated pixel layout in order to avoid crosstalk. Moreover, such solutions are very difficult to implement for small pixels.

Therefore, one preferred solution is to use inorganic light emitting diodes (LED).

For example, for automobile applications, each pixel may comprise one or several blue diodes for which radiation is converted into white light, for example with phosphorus.

Also as an example, each pixel may comprise a plurality of LEDs, each of said LEDs being capable of emitting electromagnetic radiation with a different wavelength. In particular, each pixel may comprise a diode emitting blue light (called the blue diode) a diode emitting green light (called the green diode) and a diode emitting red light (called the red diode).

An appropriate combination of intensities of radiation emitted by the blue, green and red diodes makes it possible to emit any colour in the visible range, and particularly to emit white light for lighting in the automobile industry.

These light emitting diodes generally comprise stacks of IIIV semiconducting materials, for example such as GaN or InₓGa₁₋ₓN (subsequently denoted InGaN).

In this respect, information necessary for the design of a LED based on these materials is given in document [1] mentioned at the end of the description.

In particular, a light emitting diode comprises two external layers made of an n-doped semiconducting material and a p-doped semiconducting material respectively (for example based on InGaN) between which an active layer is intercalated.

Throughout the description, the layer of a LED from which electromagnetic radiation is emitted is designated the active layer.

In particular, the active layer of a LED may comprise a stack of quantum wells as described on page 9, lines 8-17 in document [2] mentioned at the end of the description.

When they are stacked, the LEDs can be separated from each other by tunnel junctions as specified on page 9 lines 27-28 in document [2].

FIGS. 1a to 1f illustrate the different steps in a method for manufacturing at least one light emitting structure 1, and particularly at least one pixel, for example that has three LEDs called the first LED, the second LED and the third LED, each of which can emit electromagnetic radiation with a different wavelength.

This method comprises the following steps:

a) supply a support substrate 2 that has a face called the front face 2a;

b) formation, for example by epitaxy, of a stack of layers, the stack of layers comprises a succession of light emitting stacks called, starting from the front face, the first stack 3, the second stack 4 and the third stack 5 respectively, that will form the first LED 3L, the second LED 4L and the third LED 5L respectively (FIG. 1a);

c) a step to etch the third stack that will define the third LED (FIG. 1b);

d) a step to etch the second stack that will define the second LED and the first LED (FIG. 1c).

This method can also comprise the formation of contacts, called upper contacts on the exposed face of the p-doped semiconducting layer of each of the first, second and third LEDs.

This step in the formation of upper contacts implies particularly the use of a photolithography and metallisation step.

Other contacts, called lower contacts, are intended to polarise the n-doped semi-conducting layer in each of the LEDs.

Thus, each LED comprises two contacts.

However, such a method is not satisfactory.

The topology imposed by successive etchings (steps c and d) makes it complicated if not impossible to put the upper contacts of each diode in common.

Furthermore, two distinct photolithography steps specifically aimed at the formation of firstly upper contacts and secondly lower contacts are necessary.

Furthermore, the etching steps c) and d) also require one photolithography step for each light emitting diode per pixel, for definition of the LEDs.

Considering the relatively severe alignment tolerances, particularly when the pixel size reduces, the multiplication of photolithography steps makes the method more complicated, and comprises the efficiencies associated with manufacturing of such structures.

More particularly, this problem is particularly important when the first etching generates a topology at the exposed surface that complicates the use of subsequent photolithography steps. In particular, the photosensitive resin used in the photolithography step may have uneven thicknesses when the surface on which it is spread is not plane.

Furthermore, the surface topology resulting from successive etchings complicates a possible transfer of structures onto a substrate, and makes it very difficult if not impossible to perform the pixel connection step, particularly to a control circuit (hybridisation phase).

One purpose of this invention is then to disclose a method for manufacturing light emitting structures that is easier to implement that methods known according to the state of the art.

Another purpose of this invention is also to disclose a method for manufacturing light emitting structures that has fewer photolithography steps than the method known according to the state of the art.

Another purpose of this invention is also to disclose a method for manufacturing light emitting structures provided with a plurality of LEDs with coplanar exposed faces.

### PRESENTATION OF THE INVENTION

The purposes of this invention are at least partially achieved by a method of manufacturing at least one optoelectronic structure formed by a plurality of light emitting diodes, each intended to emit electromagnetic radiation with a different wavelength, the method comprising the following steps:

a) a step to supply a support substrate that comprises at least one cavity on a first face, the bottom of which cooperates with the first face to form steps with essentially equal heights, called step heights;

b) an epitaxy step to form a stack of layers on the first face, comprising a sequence of light emitting stacks each of which will form a light emitting diode, and each of which has a thickness essentially equal to the step height such that the exposed surface of said stack reproduces the step profile, the step thus reproduced set back furthest defining a reference level;

c) a step to level the stack of layers relative to the reference level so as to expose a different light emitting stack section on each step and vertically in line with each step, to the external environment, each of the light emitting stack sections thus exposed forming one of the diodes among the plurality of light emitting diodes

Thus, the method can form coplanar diodes, and consequently simplify the method of forming them.

Furthermore, coplanarity of the diodes also makes it possible to integrate at least one structure to another device such as a control device.

Cointegration generally requires bonding or hybridisation steps that, in the framework of this invention, are simplified due to coplanarity of the light emitting diodes.

Furthermore, a single levelling step is required to reveal each of the diodes, while a plurality of etching steps were necessary in methods known in prior art.

Coplanarity of the light emitting diodes facilitates interfacing them with a control circuit and/or any other microelectronic, MEMS, MOEMS device.

The interface of an optoelectronic structure obtained according to the terms of this invention can in particular involve one or several assembly steps, particularly direct bonding of substrates.

According to one embodiment, the levelling step comprises a polishing step, advantageously a mechanical-chemical polishing step.

According to one embodiment, a layer of dielectric material is deposited on all the risers of the steps formed by the bottom and the first face, the layer of dielectric material being intended to prevent epitaxial growth on the risers of the steps and thus orient the stack of layers along a direction perpendicular to said steps.

The dielectric material can comprise silicon dioxide, or silicon nitride.

According to one embodiment, each light emitting diode comprises a layer of n-doped semiconducting material, called the lower layer on which there is an active layer, and a p-doped semiconducting layer called the upper layer, in order, the active layer being adapted to emit an electromagnetic wave with wavelength k when an electric current passes through it, the active layer advantageously comprising a stack of a plurality of quantum wells.

According to one embodiment, the method also includes the formation of two electrodes called the upper and lower electrodes respectively, on each of the diodes that will enable the passage of an electric current through the active layer.

According to one embodiment, for each diode, the upper electrode is formed on the face exposed to the environment of the upper layer, advantageously the upper electrode covers the entirety of the face exposed to the environment of said upper layer.

Once it covers the upper layer of the diode, the electrode acts as a reflector such that extraction of light through the second face of the support substrate is improved.

According to one embodiment, the lower electrode is common to each of the diodes.

According to one embodiment, formation of the lower electrodes includes the formation of trenches between immediately adjacent diodes in a same structure or in different structures, the formation of a layer of electrically insulating material on the side walls of said trenches and filling of the trenches with a metallic material.

According to one embodiment, for each diode except for the diode in direct contact with the support substrate, the lower layer rests on a tunnel junction, the tunnel junction being formed by a stack of a layer of n-doped semiconducting material and a layer of p-doped semiconducting material, advantageously the layer of p-doped semiconducting material being intercalated between the layer of semiconducting material n and the lower layer.

Thus, the contacts are made only on layers of n type material, which gives better results (lower access resistance) than on layers of p type material, especially after an etching step (planarisation step).

According to one embodiment, each trench formed between two adjacent diodes, each of which is provided with a tunnel junction, extends as far as the tunnel junctions of said diodes, such that electrical contact between the lower electrode and said diodes is made at the layers of n-doped semiconducting material of their corresponding tunnel junction.

According to one embodiment, the cavity is formed from a succession of etching steps, advantageously dry etching steps formed starting from the first face.

According to one embodiment, the formation in step b) by epitaxy is done a first face made of GaN.

According to one embodiment, the support substrate is a GaN substrate.

According to one embodiment, the support substrate is a sapphire substrate on which a GaN layer is formed, the cavity being formed in the GaN layer.

According to one embodiment, the method also comprises a step to transfer at least one optoelectronic structure onto a host substrate.

According to one embodiment, the transfer step includes the following sub-steps:

d) assembly of the at least one optoelectronic structure with a face of the host substrate called the host face;

e) removal of the support substrate advantageously performed by laser heating.

According to one embodiment, step e) is followed by a levelling step f) designed to preserve only the light emitting diodes among the remainder of the light emitting stacks resulting from levelling of the stack of layers produced in step c).

According to one embodiment, the at least one optoelectronic structure comprises three light emitting diodes called the first diode, the second diode and the third diode respectively, formed from three light emitting stacks called the first stack, the second stack and the third stack respectively, and formed in this order on the first face, the first, second and third diodes being capable of emitting magnetic radiation at wavelengths called the first, second and third wavelengths respectively, the first wavelength being less than the second wavelength that is itself less than the third wavelength.

### BRIEF DESCRIPTION OF THE DRAWINGS

Other characteristics and advantages will become clear in the following description of a method of manufacturing at least one optoelectronic device according to the invention, given as non-limitative examples, with reference to the appended drawings in which:

FIGS. 1a to 1f are diagrammatic representations of a method of manufacturing an optoelectronic structure according to a method, FIGS. 1a to 1f represent a section through the support substrate in a section plane perpendicular to the first face, in different steps of a method;

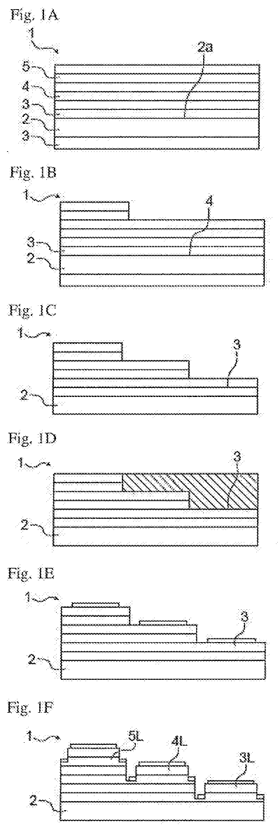

FIGS. 2a to 2f are diagrammatic representations of a method of manufacturing an optoelectronic structure according to a first embodiment of this invention, FIGS. 2a to 2f represent a section through the support substrate in a section plane perpendicular to the first face, in the different steps of the method;

FIGS. 3a to 3d are diagrammatic representations of a method of forming a plurality of cavities from a first face of a support substrate that can be used in execution of the method according to this invention;

FIG. 4 is a diagrammatic representation of a support substrate after step b) and for which the layer of dielectric material and the tunnel junctions are considered;

FIGS. 5a and 5b are diagrammatic representations of steps to transfer the optoelectronic structure from the support substrate to a host substrate relating to a second embodiment of this invention.

### DETAILED PRESENTATION OF PARTICULAR EMBODIMENTS

This invention discloses details of a method of manufacturing at least one optoelectronic structure on a support substrate.

In particular, this invention relates to manufacturing of an optoelectronic structure that has a plurality of coplanar light emitting diodes, and formed from a succession of light emitting stacks.

Therefore this invention uses a cavity, the bottom of which has a staged profile, such that the formation of the succession of light emitting stacks reproduces the staged profile of the bottom of the cavity, on its exposed face.

Performance of a step to level the succession of light emitting stacks relative to a reference level defined by the exposed surface portion vertically in line with the deepest step, then makes it possible to reveal a set of coplanar light emitting diodes.

The description of this invention makes use of specific terms and expressions that are defined below, for clarification purposes.

The terms “upper” and “lower” are defined with reference to the figures appended to this invention.

In particular, these terms are defined relative to the orientation of the support substrate 100 when this support substrate is arranged to be horizontal with its first face oriented upwards.

“In order” means particularly an enumeration of elements (for example layers), particularly from an element closest to a reference, to an element furthest from this reference.

The reference may be a support such as a support substrate, and particularly its first face.

“Starting from” is also used to enumerate elements, particularly layers, in the order in which they appear relative to a reference.

In particular, an enumeration of layers from a face and in order, will list said layers, from the layer closest to said face to the layer furthest from said face.

“Exposed to the environment” or “exposed to the external environment” means an element on which no other element rests, for example a face or a free surface.

“Stack” or set of layers” means layers resting on each other.

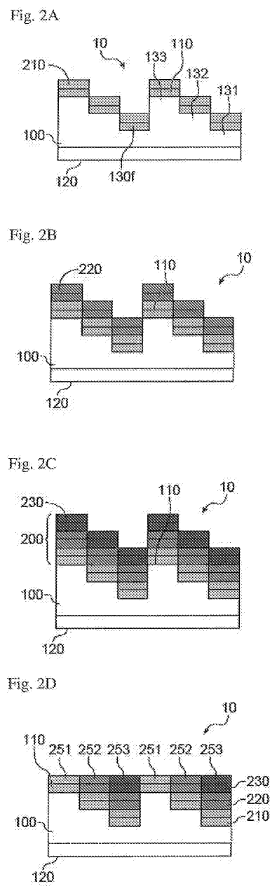

FIGS. 2a to 2f are diagrammatic representations of different steps in the method of manufacturing an optoelectronic structure 10 formed from a plurality of light emitting diodes each of which will emit electromagnetic radiation at a different wavelength according to a first embodiment of this invention.

In particular, the method according to this invention comprises a step a) to supply a support substrate 100.

The support substrate 100 comprises particularly two essentially parallel faces called the first face 110 and the second face 120 respectively.

The first face 110 can be monocrystalline, and in particular may comprise a monocrystalline semiconducting material.

For example, the support substrate 100 may comprise solid gallium nitride (GaN).

Alternatively, the support substrate 100 may comprise a sapphire substrate on which a monocrystalline layer of GaN is formed.

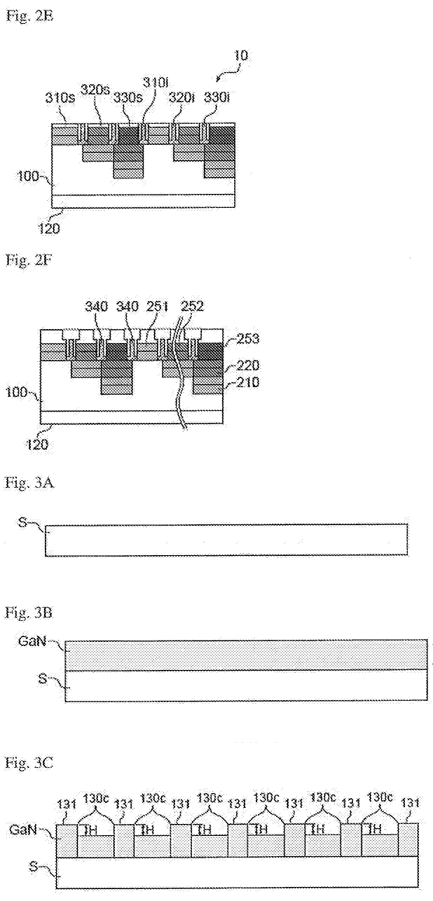

This substrate, as illustrated in FIGS. 3a and 3b, may in particular be obtained by epitaxial growth of GaN on a substrate S.

The substrate S may be a transparent substrate, and in this respect may include at least one element chosen from among sapphire, silicon carbide (SiC), spinel (for example MgAl₂O₄), zinc oxide (ZnO).

Alternatively, the substrate S may be absorbent, and for example may comprise at least one element chosen from among silicon (Si), composite substrates containing silicon (for example SOI).

The support substrate 100 according to this invention also comprises one or several cavities 130 formed starting from its first face 110.

The cavities 130 may be arranged in matrix form.

The cavity 130 comprises a wall 130p and a bottom called the staged bottom 130f, that cooperate with the first face to form a plurality of steps 131, 132, 133, each of the steps having the same height H, called the step height H (FIG. 3d).

The cavity 130 is delimited by a contour 130c, for example a rectangular shaped contour 130c.

Formation of the cavity 130 may include the performance of a plurality of etching steps, and particularly dry etching steps (FIGS. 3c to 3d).

In particular, formation of a cavity 130, of which the staged bottom 130f together with the first face forms three steps 131, 132, 133, may include the execution of etching steps called the first etching and the second etching respectively.

The first etching (FIG. 3c) can then include the formation of a first sub-cavity delimited by the contour 130c and a depth corresponding to the step height H.

The second etching (FIG. 3d) can then include the formation of a second sub-cavity starting from the bottom of the first sub-cavity and that will define the deepest step of the staged bottom 130f.

The second sub-cavity also has a depth H relative to the bottom of the first sub-cavity.

The method according to this invention also comprises a step b) for the formation of a stack of layers 200 formed on the first face 110 of the support substrate 100.

The stack of layers 200 also comprises in particular a succession of light emitting stacks 210, 220, 230 (FIGS. 2a to 2c).

In the remainder of the description, the number of light emitting stacks is limited to three light emitting stacks for reasons of clarity, called, starting from the first face 119, the first light emitting stack 210, the second light emitting stack 220 and the third light emitting stack 230.

However, after reading the description, an expert in the subject would be capable of generalising the concepts presented and reproducing this invention with another number of light emitting diodes.

As will become clear in the remainder of the description, each of these light emitting stacks will form one of the diodes among the plurality of diodes in the light emitting structure.

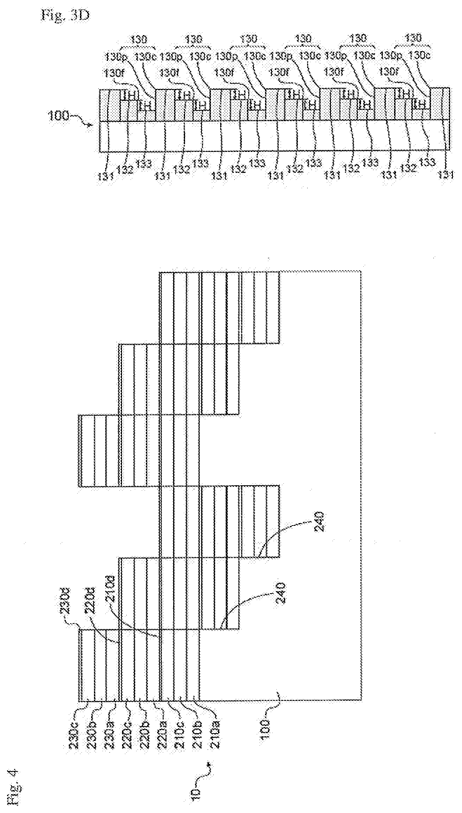

Thus, each of the light emitting stacks may comprise a layer of n-doped semiconducting material 210a, 220a, 230a, called the lower layer 210a, 220a, 230a, on which an active layer 210b, 220b, 230b and a layer of p-doped semiconductor called the upper layer 210c, 220c, 230c are supported, in order (FIG. 4).

In particular, the active layer is adapted to emit an electromagnetic wave with wavelength λ when an electric current passes through it, and advantageously comprises a plurality of quantum wells.

Thus, the first light emitting stack 210 comprises a first lower layer 210a, a first active layer 210b, and a first upper layer 210c, in order and starting from the first face 110.

The second light emitting stack 220 comprises a second lower layer 220a, a second active layer 220b, and a second upper layer 220c, in order and starting from the first upper layer 210c.

The third light emitting stack 230 comprises a third lower layer 230a, a third active layer 230b, and a third upper layer 230c, in order and starting from the second upper layer 220c.

Particularly advantageously, the light emitting stacks can be arranged such that the wavelength λ, that can be emitted by the active layer of each light emitting stack is longer than the wavelength that can be emitted by the active layer of the subjacent stack.

For example, the active layers of the first, the second and the third stacks can be adapted to emit blue, green and red radiation respectively.

The upper layer and the lower layer of each light emitting stack can include p- and n-doped GaN, respectively.

The active layer of a light emitting stack may comprise a stack of quantum wells, for example a stack of (Ga, In)N/(Al, Ga, In)N quantum wells, particularly 5 periods of In_{0.15}Ga_{0.85}N (2 nm)/GaN (10 nm) for the emission of blue radiation, or 5 periods of In_{0.40}Ga_{0.60}N (2 nm)/GaN (10 nm) for the emission of red radiation.

The layers forming the light emitting stacks may advantageously be obtained by epitaxy.

Furthermore, the thickness of the light emitting stacks is equal to the step height H, such that the exposed surface of the layer of stacks 200 reproduces the step profile, the step set back furthest thus reproduced defining a reference level.

“Step set back furthest” means the step that is set back furthest from the exposed surface of the stack of layers 200. In other words, the “step set back furthest” means the deepest level of the cavity 130.

The formation of tunnel junctions can also be considered in the framework of this invention.

In particular, each of the light emitting stacks can have a tunnel junction 210d, 220d, 230d (FIG. 4).

In particular, the tunnel junction 210a, 220a, 230a for a given light emitting stack rests on the upper layer of said stack.

A tunnel junction according to this invention may comprise a stack formed from a layer of strongly p-doped semiconducting material, and a layer of strongly n-doped semiconducting material. Such a tunnel junction is deposited after each p-doped layer of each light emitting stack.

In a particularly advantageous manner, performance of step b) may be preceded by the formation of a layer of dielectric material 240 on all the risers of steps 131, 132, 133.

Formation of this layer 240 may include the deposition of a layer of dielectric material on all the steps and the risers of at least one cavity, followed by a step to etch the dielectric material covering the steps (FIG. 4).

The dielectric material can comprise silicon oxide, or silicon nitride.

The dielectric material covering the steps can etched by dry etching (i.e. plasma etching), done anisotropically in order to selectively etch the dielectric material covering the steps.

The layer of dielectric material deposited on all the risers can prevent growth on said risers, and particularly orient the formation by epitaxy of the stack of layers along a direction perpendicular to the steps.

The method according to this invention also comprises a step c) to level the stack of layers relative to the reference level so as to expose a different section of light emitting stack on each step to the external environment, and vertically in line with each step.

Each light emitting stack section thus exposed forms one of the diodes among the plurality of light emitting diodes.

In other words, the deepest step 133 keeps the stack of layers 200 in its entirety, while after step c) the least deep step 131 (defined by the first face 110) only keeps one light emitting stack, and in particular the first light emitting stack formed during step b) (FIG. 2d).

Thus, in the case of three steps and three light emitting stacks, after step c) the optoelectronic structure 10 comprises the following:
on the least deep step called the first step 131, a first diode 251 defined by the first step;
on the intermediate step, called the second step 132, a second diode 252 defined by the second stack and supported on the first stack,
on the deepest step, called the third step 133, a third diode 253 defined by the third stack and supported on the first and second stacks,

After the levelling step, each of the optoelectronic structures comprises a plurality of different light emitting diodes exposed to the external environment.

In particular, said diodes are coplanar, each vertically in line with a different step, and each comprises a different light emitting stack.

In particular, each light emitting diode comprises the lower layer 210a, 220a, 230a, the active layer 210b, 220b, 230b, and the upper layer 210c, 220c, 230c of the light emitting stack from which it is formed.

Each diode may also comprise a tunnel junction 1f formation of this tunnel junction is considered, covering its upper layer.

Coplanarity of diodes within the structure and from one structure to the next, simplifies the formation of contacts (described in detail below).

This coplanarity, when the support substrate is opaque to electromagnetic radiation that could be emitted by the diodes, can simplify transfer of the optoelectronic structures onto another support.

This aspect is also discussed in the framework of a second embodiment presented in the remainder of the presentation.

The levelling step c) may include a polishing step, and particularly a mechanical-chemical polishing step.

Implementation of the levelling step is part of the general knowledge of an expert in the subject, and consequently it is not described in the remainder of the description.

The method according to this invention may also include the formation of contacts intended to address diodes individually or collectively, for each said diode in each of the structures (FIG. 2e).

The formation of contacts can in particular include the formation of two free electrodes, namely the upper electrode 310s, 320s, 330s and the lower electrode 310i, 320i, 330i respectively on each diode, intended to allow the passage of an electric current through the active layer 210b, 220b, 230b.

More particularly, when the optoelectronic structure comprises three diodes, a first upper electrode 310s and a first lower electrode 310i are formed to contact the first diode 251, a second upper electrode 320s and a second lower electrode 320i are formed to contact the second diode 252, a third upper electrode 330s and a third lower electrode 330i are formed to contact the third diode 253.

The upper electrodes 310s, 320s, 330s can be formed on the upper layer of each of the diodes.

Advantageously, the upper electrode covers the entire upper layer.

However, contact between the upper electrode and the p-doped upper layer can cause high access resistance. This phenomenon is then exacerbated by the surface condition of the upper layer resulting from step c).

Alternatively, in order to mitigate this problem, the upper electrode can cover the n-doped layer of the tunnel junction when this tunnel junction is considered.

The formation of the lower electrodes may include the formation of trenches 340 (FIG. 2f) between the diodes immediately adjacent to one structure 10 or adjacent structures 10.

Formation of the trenches is then followed by formation of a layer of electrically insulating material on the side walls of said trenches 340 and filling of the trenches by a metallic material.

Advantageously, the lower electrode is common to each diode in at least one optoelectronic structure.

The trenches 340 formed between adjacent diodes can extend as far as the tunnel junctions of said diodes, such that electrical contact between the lower electrode and said diodes is made at the layers of n-doped semiconducting material of their corresponding tunnel junction.

Due to the fact that the diodes are coplanar, the formation of each of the lower electrodes and upper electrodes requires fewer photolithography steps than the method described in the prior art section.

Consequently, the formation of electrodes is no longer constrained by alignment constraints and therefore it becomes possible to envisage the formation of optoelectronic structures provided with relatively small diodes, and particularly diodes of the order of a micrometre.

If the support substrate 100 is transparent to radiation that can be emitted by the different diodes, said radiation can pass through said support.

The upper electrodes can act as reflectors such that radiation produced by the diodes is extracted from the second face of the support substrate 100 (FIG. 2f, emitted radiation is symbolised by the arrows).

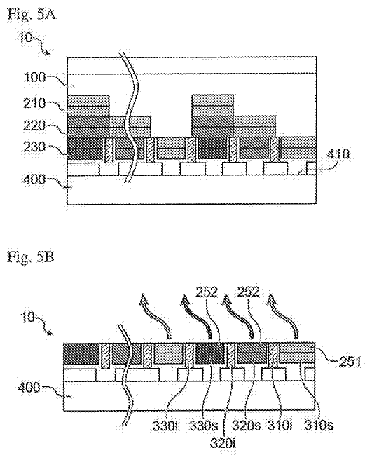

If the support substrate 100 is opaque to radiation that can be emitted by the diodes, according to a second embodiment of the invention, it could be envisaged to transfer the optoelectronic structures onto a host substrate 400, particularly a transparent host substrate, as illustrated on FIGS. 5a and 5b.

In particular, the transfer step can include the following sub-steps:

d) assembly of the at least one optoelectronic structure with a face of the host substrate 400 called the host face 410;

e) removal of the support substrate, advantageously done for example with laser heating or by mechanical abrasion, or by mechanical-chemical polishing.

For example, the assembly step d) may include direct bonding, or through an intermediate layer such as a glue.

The assembly step may also include hybridisation with a host substrate that includes a read circuit on its host face.

This step, known to an expert in the subject, is not described in further detail.

However, it is significant that the assembly step is simplified, considering coplanarity of the diodes.

The removal step may be done, for example, with laser heating, particularly using the “laser lift off” technique, or by mechanical abrasion, or by mechanical-chemical abrasion.

However, the invention must not be limited to this technique alone, and an expert in the subject can envisage any other technique that could be suitable, particularly dry or liquid etching, abrasion.

The transfer can also be followed by a levelling step f) such that, among the remaining parts of the light emitting stacks output from step c), all that remains are the light emitting diodes.

Step f), like step c), can also be done by polishing and particularly by mechanical-chemical polishing.

Therefore the method according to this invention can be used to make light emitting structures, using a method that is simpler than methods known in prior art.

In particular, the method according to this invention can limit the number of photolithography steps, and consequently opens the way for the integration of relatively small diodes.

Coplanarity of the light emitting diodes facilitates interfacing them with a control circuit and/or any other microelectronic, MEMS, MOEMS device.

The interface of an optoelectronic structure obtained according to the terms of this invention can in particular involve one or several assembly steps, particularly direct bonding of substrates.

### REFERENCES

[1] U.S. Pat. No. 8,058,663;
[2] WO 2015/150281.

1. A method of manufacturing at least one optoelectronic structure formed from a plurality of light emitting diodes each intended to emit electromagnetic radiation with a different wavelength, the method including the following steps:
a) a step to supply a support substrate that comprises at least one cavity on a first face, the bottom of which cooperates with the first face to form steps with essentially equal heights, called step heights;
b) an epitaxy step to form a stack of layers on the first face, comprising a sequence of light emitting stacks each of which will form a light emitting diode, and each of which has a thickness essentially equal to the step height such that the exposed surface of said stack reproduces the step profile, the step thus reproduced set back furthest defining a reference level;
c) a step to level the stack of layers relative to the reference level so as to expose a different light emitting stack section on each step and vertically in line with each step, to the external environment, each of the light emitting stack sections thus exposed forming one of the diodes among the plurality of light emitting diodes.

2. The method according to claim 1, wherein the levelling step comprises a polishing step.

3. The method according to claim 1, wherein a layer of dielectric material is deposited on all the risers of the steps formed by the bottom and the first face, the layer of dielectric material being intended to prevent epitaxial growth on the risers of the steps and thus orient the formation of the stack of layers by epitaxy along a direction perpendicular to said steps.

4. The method according to claim 1, wherein each light emitting diode comprises a layer of n-doped semiconducting material, called the lower layer on which there is an active layer, and a p-doped semiconducting layer called the upper layer, in order, the active layer being adapted to emit an electromagnetic wave with wavelength λ when an electric current passes through it, the active layer.

5. The method according to claim 4, wherein the method also includes the formation of two free electrodes, namely the upper electrode and the lower electrode respectively on each diode, intended to allow the passage of an electric current through the active layer.

6. The method according to claim 5, wherein, for each diode, the upper electrode is formed on the face exposed to the environment of the upper layer.

7. The method according to claim 5, wherein the lower electrode is common to each diode in at least one optoelectronic structure.

8. The method according to claim 5, wherein formation of the lower electrodes includes the formation of trenches between immediately adjacent diodes in a same structure or in different structures, the formation of a layer of electrically insulating material on the side walls of said trenches and filling of the trenches with a metallic material.

9. The method according to claim 8, wherein for each diode except for the diode in direct contact with the support substrate, the lower layer rests on a tunnel junction, the tunnel junction being formed by a stack of a layer of p-doped semiconducting material and a layer of n-doped semiconducting material.

10. The method according to claim 9, wherein each trench formed between two adjacent diodes, each of which is provided with a tunnel junction, extends as far as the tunnel junctions of said diodes, such that electrical contact between the lower electrode and said diodes is made at the layers of n-doped semiconducting material of their corresponding tunnel junction.

11. The method according to claim 1, wherein the cavity is formed from a succession of etching steps.

12. The method according to claim 1, wherein the formation in step b) by epitaxy is done a first face made of GaN.

13. The method according to claim 12, wherein the support substrate is a GaN substrate.

14. The method according to claim 12, wherein the support substrate is a sapphire substrate on which a GaN layer is formed, the cavity being formed in the GaN layer.

15. The method according to claim 1, wherein the method also comprises a step to transfer at least one optoelectronic structure onto a host substrate.

16. The method according to claim 15, wherein the transfer step comprises the following sub-steps:
d) assembly of the at least one optoelectronic structure with a face of the host substrate (400) called the host face;
e) removal of the support substrate.

17. The method according to claim 15, wherein step e) is followed by a levelling step f) designed to preserve only the light emitting diodes among the remainder of the light emitting stacks resulting from levelling of the stack of layers produced in step c).

18. The method according to claim 1, wherein the at least one optoelectronic structure comprises three light emitting diodes called the first diode, the second diode and the third diode respectively, formed from three light emitting stacks called the first stack, the second stack and the third stack respectively, and formed in this order on the first face, the first, second and third diodes being capable of emitting magnetic radiation at wavelengths called the first, second and third wavelengths respectively, the first wavelength being less than the second wavelength that is itself less than the third wavelength.
